(19) United States
(12) Patent Application Publication
(10) Pub. No.: US 2026/0040434 A1
(43) Pub. Date: Feb. 5, 2026

(54) CHARACTERISTIC IMPEDANCE CONTROL STRUCTURE

(71) Applicant: INDUSTRIAL TECHNOLOGY RESEARCH INSTITUTE, Hsinchu (TW)

(72) Inventors: Hsiang En DING, Tainan City (TW); Shih-Hsien WU, Taoyuan City (TW)

(73) Assignee: INDUSTRIAL TECHNOLOGY RESEARCH INSTITUTE, Hsinchu (TW)

(21) Appl. No.: 18/989,160

(22) Filed: Dec. 20, 2024

Related U.S. Application Data
(60) Provisional application No. 63/678,441, filed on Aug. 1, 2024.

(51) Int. Cl. H05K 1/02

(52) U.S. Cl. CPC H05K 1/0251; H05K 1/0215; H05K 1/0245

(57) ABSTRACT

A characteristic impedance control structure includes a first and a second transmission line, a ground pattern and a ground component. The first transmission line and the ground pattern extend along a plane. The ground pattern is spaced from the first transmission line by a first distance. The second transmission line extends along a direction and electrically connects to the first transmission line. An angle between the direction and the plane is greater than zero. The second transmission line has an outer diameter. The ground component extends along the direction and is electrically connected to the ground pattern. The ground component is next to and spaced from the second transmission line by a second distance. The ground component has a length along the direction. The first distance is less than or equal to twice the length. The second distance is less than or equal to five times the outer diameter.

This non-provisional application claims priority under 35 U.S.C. § 119(a) on provisional application No. 63/678,441 filed in U.S.A. on Aug. 1, 2024, the entire contents of which are hereby incorporated by reference.

### TECHNICAL FIELD

The disclosure relates to a characteristic impedance control structure.

### BACKGROUND

The conventional circuit structure mainly uses transmission lines for horizontal signal transmission. When a signal is to be transmitted from a layer of the transmission lines to another level, a conductor column is usually used for vertical signal transmission. Thereby, it allows the signal to be transmitted through layers.

However, as the times progress, the frequency of transmitted signals becomes higher and higher, and the characteristic impedance of the transmission line and the characteristic impedance of the conductor column in the circuit structure more need to be matched with each other. When the characteristic impedance of the conductor column does not match the characteristic impedance of the transmission line, the signals are easily reflected due to the different characteristic impedances on the transmission path, which further causes unnecessary signal transmission consumption. As the frequency of the transmitted signal increases, the problem of signal distortion caused by signal reflection becomes more severe.

### SUMMARY

The objective of this disclosure is to provide a characteristic impedance control structure, which may match the characteristic impedances on the transmission path.

One embodiment of the disclosure provides a characteristic impedance control structure, including a first transmission line, a first ground pattern, a second transmission line and a ground component. The first transmission line extends along a first plane. The first ground pattern extends along the first plane. The first ground pattern is spaced from the first transmission line by a first distance. The second transmission line extends along a direction and is electrically connected to the first transmission line. A first angle between the direction and the first plane is greater than zero. The second transmission line has an outer diameter. The ground component extends along the direction and is electrically connected to the first ground pattern. The ground component is next to and spaced from the second transmission line by a second distance. The ground component has a length along the direction. The first distance is less than or equal to twice the length. The second distance is less than or equal to five times the outer diameter.

According to the characteristic impedance control structure as discussed in the above embodiments, by means of the corresponding relationship of the distance between the first transmission line and the ground pattern, the size of the second transmission line, the size of the ground component and the distance between the second transmission line and the ground component, the characteristic impedances of the first transmission line and the second transmission line may be matched with each other. When the first transmission line and the second transmission line are used to transmit a high frequency signal, it may prevent the signal passing through the transmission path from being distorted due to characteristic impedance mismatch.

The above descriptions in the summary and the following detailed descriptions are used to demonstrate and explain the spirit and principle of the disclosure and provide a further explanation of the scope of the claims of the disclosure.

### BRIEF DESCRIPTION OF THE DRAWINGS

The disclosure will become better understood from the detailed description given hereinbelow and the accompanying drawings which are given by way of illustration only and thus are not intending to limit the disclosure and wherein:

FIG. 1 illustrates a schematic three-dimensional view of a characteristic impedance control structure according to one embodiment of the disclosure;

FIG. 2 illustrates a schematic top view of the characteristic impedance control structure in FIG. 1;

FIG. 3 illustrates a schematic side cross-sectional view along line III-III of the characteristic impedance control structure in FIG. 1;

FIG. 4 illustrates a schematic three-dimensional view of a characteristic impedance control structure according to another embodiment of the disclosure;

FIG. 5 illustrates a schematic side cross-sectional view of the characteristic impedance control structure in FIG. 4;

FIG. 6 illustrates a schematic top view of the characteristic impedance control structure in FIG. 4;

FIG. 7 illustrates a schematic top cross-sectional view along line VII-VII of the characteristic impedance control structure in FIG. 4;

FIG. 8 illustrates a schematic top cross-sectional view along line VIII-VIII of the characteristic impedance control structure in FIG. 4;

FIG. 9 illustrates a schematic top cross-sectional view along line IX-IX of the characteristic impedance control structure in FIG. 4;

FIG. 10 illustrates a schematic side cross-sectional view of a characteristic impedance control structure according to another embodiment of the disclosure;

FIG. 11 illustrates a schematic side cross-sectional view of a characteristic impedance control structure according to another embodiment of the disclosure;

FIG. 12 illustrates a schematic side cross-sectional view of a characteristic impedance control structure according to another embodiment of the disclosure;

FIG. 13 illustrates a schematic side cross-sectional view of a characteristic impedance control structure according to another embodiment of the disclosure;

FIG. 14 illustrates a schematic top cross-sectional view of the characteristic impedance control structure in FIG. 13;

FIG. 15 illustrates a schematic top cross-sectional view along line XV-XV of the characteristic impedance control structure in FIG. 13;

FIG. 16 illustrates a schematic top cross-sectional view along line XVI-XVI of the characteristic impedance control structure in FIG. 13;

FIG. 17 illustrates a schematic top cross-sectional view along line XVII-XVII of the characteristic impedance control structure in FIG. 13;

FIG. 18 illustrates a schematic top cross-sectional view along line XVIII-XVIII of the characteristic impedance control structure in FIG. 13; and

FIG. 19 illustrates a schematic top cross-sectional view along line XIX-XIX of the characteristic impedance control structure in FIG. 13.

### DETAILED DESCRIPTION

Features and advantages of embodiments of the disclosure are described in the following detailed description, it allows the person skilled in the art to understand the technical contents of the embodiments of the disclosure and implement them. Based on the disclosure, the claims, and the drawings, the person skilled in the art can easily comprehend the purposes of the advantages of the disclosure. The following embodiments are further illustrating the perspective of the disclosure, but not intending to limit the scope of the disclosure in any way.

The drawings may not be drawn to actual size, proportions, or angles, some exaggerations may be necessary in order to emphasize basic structural relationships, while some are simplified for clarity of understanding, but the disclosure is not limited thereto. Various modifications may be made without departing from the spirit of the disclosure. In addition, the spatially relative terms, such as “up”, “top”, “above”, “down”, “low”, “left”, “right”, “front”, “rear”, and “back” and the like, may be used herein for ease of description to describe the relationship of one element or feature to another element(s) of feature(s) as illustrated in the drawings. It will be understood that the spatially relative terms are intended to encompass orientations of the element or feature but not intended to limit the disclosure.

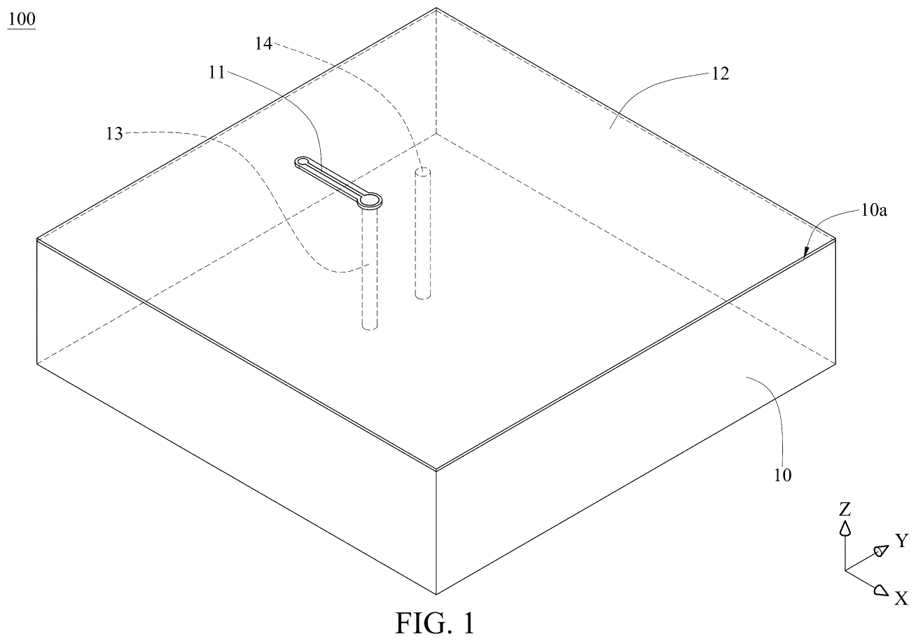

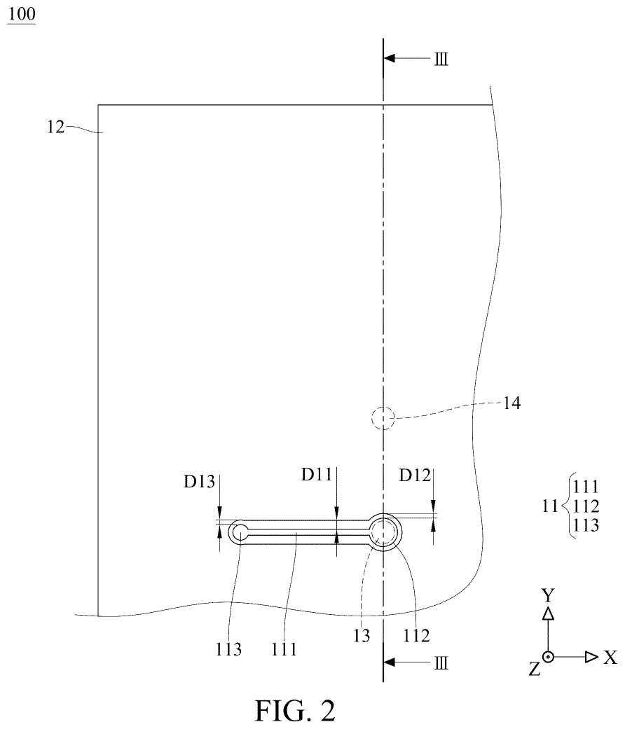

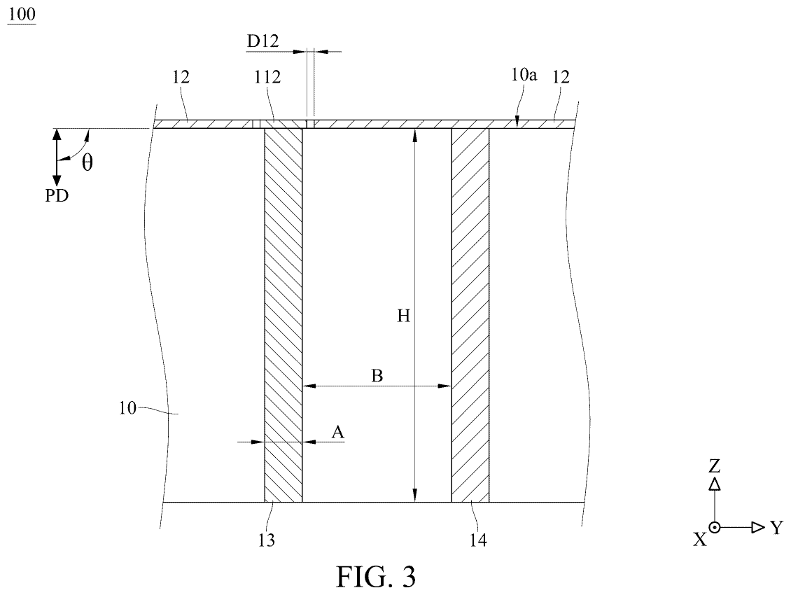

Please refer to FIG. 1 to FIG. 3. FIG. 1 illustrates a schematic three-dimensional view of a characteristic impedance control structure according to one embodiment of the disclosure. FIG. 2 illustrates a schematic top view of the characteristic impedance control structure in FIG. 1. FIG. 3 illustrates a schematic side cross-sectional view along line III-III of the characteristic impedance control structure in FIG. 1.

As shown in FIG. 1 to FIG. 3, in this embodiment, the characteristic impedance control structure 100 includes a substrate 10, a first transmission line 11, a ground pattern 12, a second transmission line 13 and a ground component 14. The substrate 10 may be a printed circuit board, a glass substrate, a silicon substrate or other substrates commonly used in circuits. The substrate 10 has an upper surface 10a. The upper surface 10a is a plane. The first transmission line 11 and the ground pattern 12 extend along the upper surface 10a. The upper surface 10a is substantially parallel to a XY plane in the figure. The first transmission line 11 includes a line part 111 and a plurality of pad parts 112, 113 connected to each other. The pad parts 112, 113 are used to be electrically connected to other elements. The ground pattern 12 is spaced from the line part 111 of the first transmission line 11 by a first distance D11. The ground pattern 12 is spaced from the pad part 112 by a first distance D12. The ground pattern 12 is spaced from the pad part 113 by a first distance D13.

The second transmission line 13 extends along a direction PD and is electrically connected to the pad part 112 of the first transmission line 11. The second transmission line 13 penetrates through the substrate 10. The second transmission line 13 has an outer diameter A. An angle θ between the direction PD and the upper surface 10a is greater than zero. The direction PD is substantially parallel to a Z direction in the figure. In this embodiment, the direction PD is substantially perpendicular to the upper surface 10a of the substrate 10, but the disclosure is not limited thereto. In other embodiments, the angle θ may be also less than 90 degrees.

In this embodiment, the ground component 14 extends along the direction PD and is electrically connected to the ground pattern 12. The ground component 14 penetrates through the substrate 10. The ground component 14 is next to and spaced from the second transmission line 13 by a second distance B. The ground component 14 has a length H along the direction PD. Each of the first distances D11, D12, D13 is less than or equal to twice the length H (that is D11≤2H, D12≤2H, and D13≤2H). The second distance B is less than or equal to five times the outer diameter A (that is B≤5A).

In this embodiment, the transmission path includes the first transmission line 11 and the second transmission line 13. By means of the corresponding relationship of the above-mentioned size, the characteristic impedances of the first transmission line 11 and the second transmission line 13 may be matched with each other. When the first transmission line 11 and the second transmission line 13 are used to transmit a high frequency signal, it may prevent the signal passing through the transmission path from being distorted due to characteristic impedance mismatch.

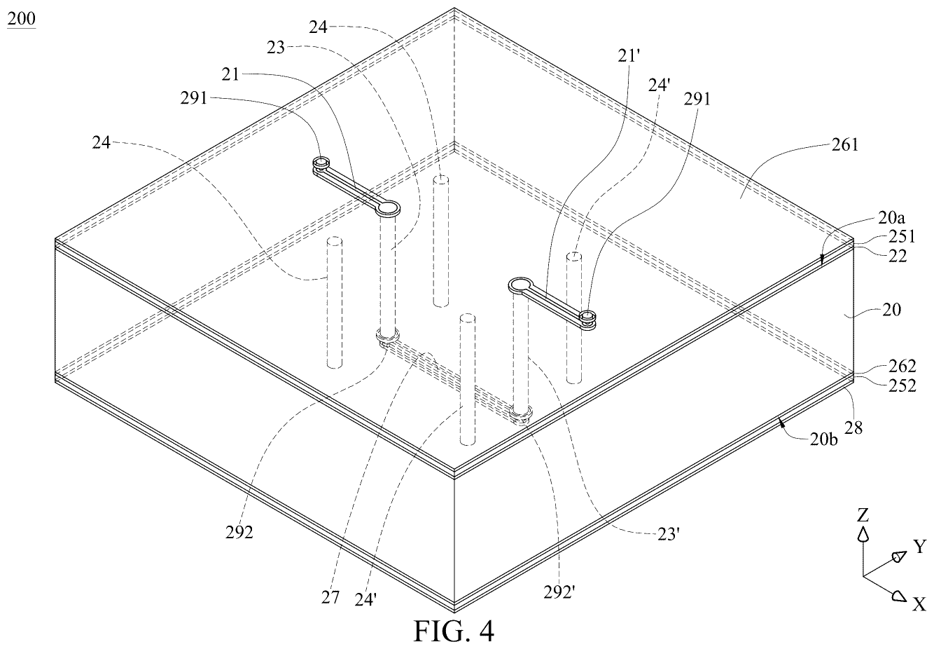

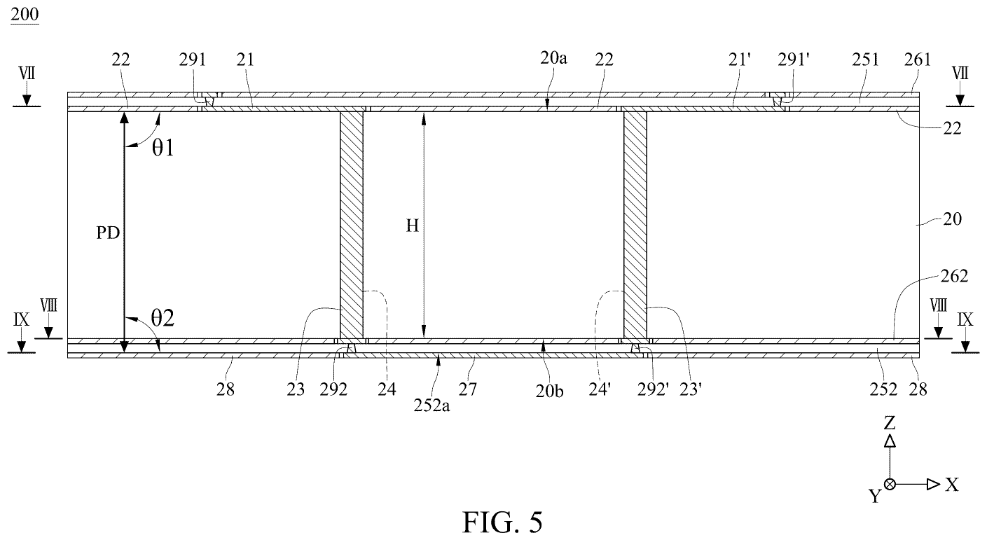

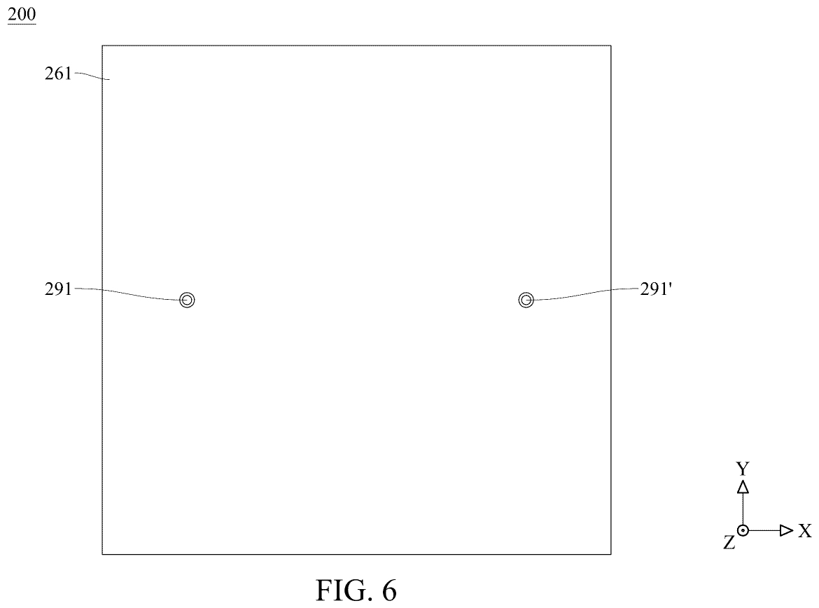

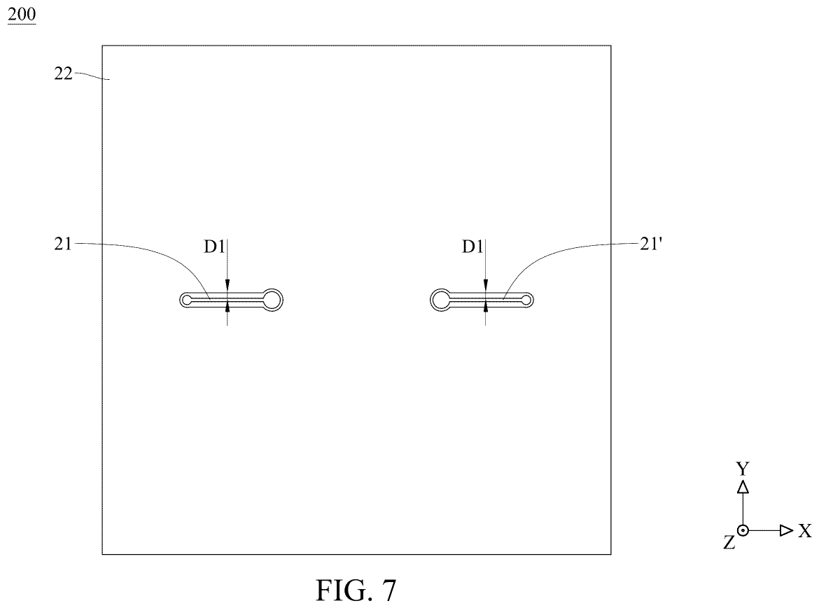

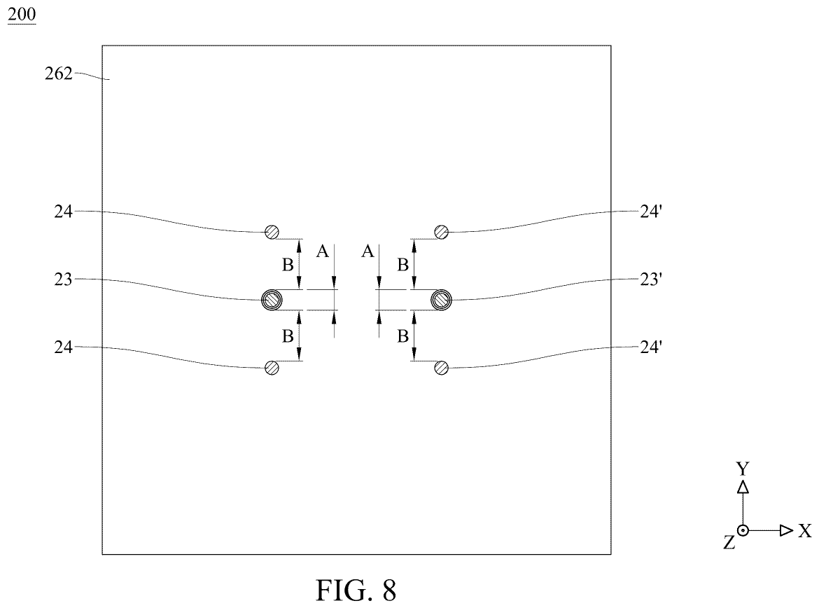

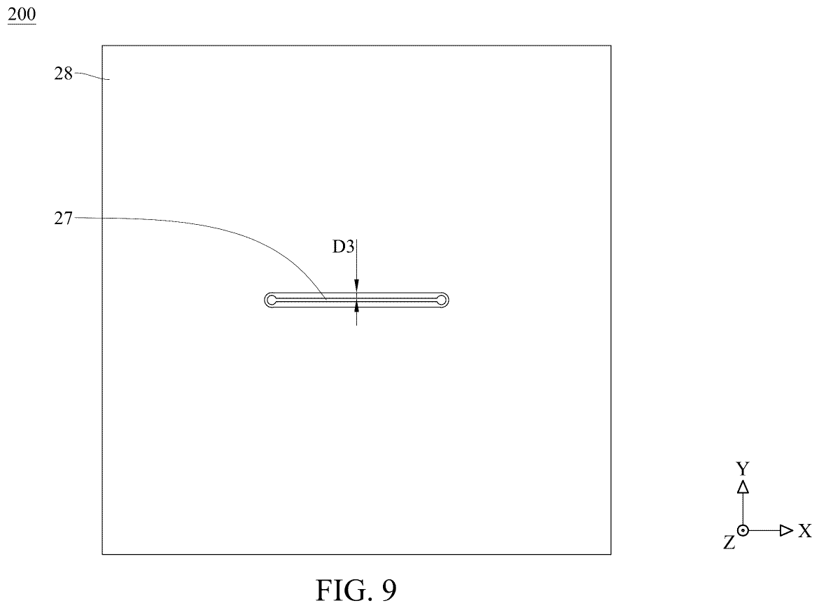

Please refer to FIG. 4 to FIG. 9. FIG. 4 illustrates a schematic three-dimensional view of a characteristic impedance control structure according to another embodiment of the disclosure. FIG. 5 illustrates a schematic side cross-sectional view of the characteristic impedance control structure in FIG. 4. FIG. 6 illustrates a schematic top view of the characteristic impedance control structure in FIG. 4. FIG. 7 illustrates a schematic top cross-sectional view along line VII-VII of the characteristic impedance control structure in FIG. 4. FIG. 8 illustrates a schematic top cross-sectional view along line VIII-VIII of the characteristic impedance control structure in FIG. 4. FIG. 9 illustrates a schematic top cross-sectional view along line IX-IX of the characteristic impedance control structure in FIG. 4.

As shown in FIG. 4 and FIG. 5, in this embodiment, the characteristic impedance control structure 200 includes a substrate 20, a plurality of first transmission lines 21, 21′, a first ground pattern 22, a plurality of second transmission lines 23, 23′, a plurality of ground lines 24, 24′, a first dielectric layer 251, a second dielectric layer 252, a first ground layer 261, a second ground layer 262, a third transmission line 27, a second ground pattern 28 and a plurality of conductive vias 291, 291′, 292, 292′. The substrate 20 may be a printed circuit board, a glass substrate, a silicon substrate or other substrates commonly used in circuits. The substrate 20 has an upper surface 20a and a lower surface 20b opposite to each other. The upper surface 20a is a first plane. The first transmission lines 21, 21′ and the first ground pattern 22 are disposed on the upper surface 20a of the substrate 20. The first transmission lines 21, 21′ and the first ground pattern 22 extend along the upper surface 20a. The upper surface 20a is substantially parallel to a XY plane in the figure.

As shown in FIG. 5, FIG. 7 and FIG. 8, the first ground pattern 22 is spaced from each of the first transmission lines 21, 21′ by a first distance D1. The second transmission lines 23, 23′ extend along a direction PD and are respectively electrically connected to the first transmission lines 21, 21′. The second transmission lines 23, 23′ penetrate through the substrate 20. Each of the second transmission lines 23, 23′ has an outer diameter A. A first angle θ1 between the direction PD and the upper surface 20a is greater than zero. The direction PD is substantially parallel to a Z direction in the figure. In this embodiment, the direction PD is substantially perpendicular to the upper surface 20a of the substrate 20, but the disclosure is not limited thereto. In other embodiments, the first angle θ1 may be also less than 90 degrees.

In this embodiment, the ground lines 24, 24′ form a ground component. The ground lines 24, 24′ extend along the direction PD and are electrically connected to the first ground pattern 22. The ground lines 24, 24′ penetrate through the substrate 20. Each of the ground lines 24, 24′ is next to and spaced from each of the second transmission lines 23, 23′ by a second distance B. The ground lines 24 are arranged around the second transmission line 23. The ground lines 24′ are arranged around the second transmission line 23′. Each of the ground lines 24, 24′ has a length H along the direction PD. The first distance D1 is less than or equal to twice the length H (that is D1≤2H) (when the first distance D1 is inconsistent, the maximum value is taken). The second distance B is less than or equal to five times the outer diameter A (that is B≤5A). In other embodiments, the ground component may be a plurality of ground tubes respectively disposed around the second transmission lines 23, 23′.

As shown in FIG. 5 and FIG. 6, in this embodiment, the first dielectric layer 251 is disposed on the first transmission lines 21, 21′, the first ground pattern 22 and the upper surface 20a of the substrate 20. The first ground layer 261 is disposed on the first dielectric layer 251. The first ground layer 261 is disposed substantially parallel to the upper surface 20a (that is substantially parallel to the first plane). In the direction PD, the first ground layer 261 is farther away from the second transmission lines 23, 23′ than the first ground pattern 22. The conductive vias 291, 291′ are respectively electrically connected to the first transmission lines 21, 21′. The conductive vias 291, 291′ penetrate through the first dielectric layer 251 and the first ground layer 261. The first transmission lines 21, 21′ may be respectively electrically connected to the outside through the conductive vias 291, 291′.

As shown in FIG. 5, FIG. 8 and FIG. 9, the second ground layer 262 is disposed on the lower surface 20b of the substrate 20. The second transmission lines 23, 23′ are spaced from the second ground layer 262. The ground lines 24, 24′ are electrically connected to the second ground layer 262. The second ground layer 262 is disposed substantially parallel to the lower surface 20b. The second dielectric layer 252 is disposed on the second ground layer 262. The third transmission line 27 and the second ground pattern 28 are disposed on the second dielectric layer 252. The second ground pattern 28 is spaced from the third transmission line 27 by a third distance D3. The third distance D3 is less than or equal to twice the length H (that is D3≤2H). The third transmission line 27 and the second ground pattern 28 extend along a lower surface 252a of the second dielectric layer 252. The lower surface 252a of the second dielectric layer 252 is a second plane. The lower surface 20b of the substrate 20 is substantially parallel to the lower surface 252a of the second dielectric layer 252. A second angle θ2 between the direction PD and the lower surface 252a of the second dielectric layer 252 is greater than zero. In this embodiment, the direction PD is substantially perpendicular to the lower surface 252a of the second dielectric layer 252, but the disclosure is not limited thereto. In other embodiments, the second angle θ2 may be also less than 90 degrees.

In this embodiment, the top ends of the second transmission lines 23, 23′ are respectively electrically connected to the first transmission lines 21, 21′. The conductive vias 292, 292′ penetrate through the second dielectric layer 252. The two ends of the third transmission line 27 are respectively electrically connected to the bottom ends of the second transmission lines 23, 23′ through the conductive vias 292, 292′. Thereby, the two ends of the second transmission line 23 are respectively electrically connected to the first transmission line 21 and the third transmission line 27. The two ends of the second transmission line 23′ are respectively electrically connected to the first transmission line 21′ and the third transmission line 27. In the direction PD, the second ground pattern 28 is farther away from the second transmission lines 23, 23′ than the second ground layer 262.

In this embodiment, the transmission path includes the first transmission line 21, the second transmission line 23, the conductive via 292, the third transmission line 27, the conductive via 292′, the second transmission line 23′ and the first transmission line 21′. By means of the corresponding relationship of the above-mentioned size, the characteristic impedances of the first transmission line 21, the second transmission line 23, the third transmission line 27, the second transmission line 23′ and the first transmission line 21′ may be matched with each other. When the first transmission line 21, the second transmission line 23, the third transmission line 27, the second transmission line 23′ and the first transmission line 21′ are used to transmit a high frequency signal, it may prevent the signal passing through the transmission path from being distorted due to characteristic impedance mismatch. In other embodiments, the conductive via 292′, the second transmission line 23′, the first transmission line 21′ and the ground line 24′ may be omitted as required.

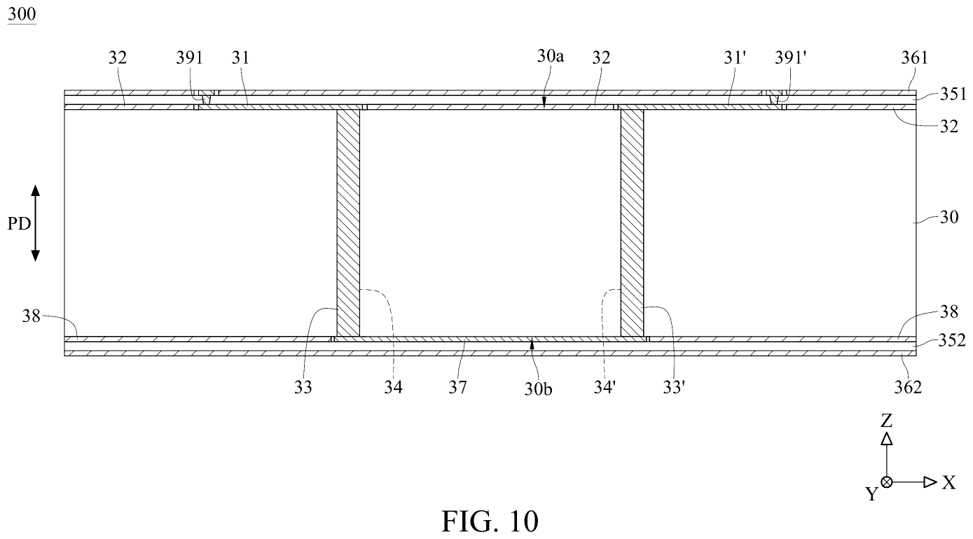

Please refer to FIG. 10. FIG. 10 illustrates a schematic side cross-sectional view of a characteristic impedance control structure according to another embodiment of the disclosure. The characteristic impedance control structure 300 shown in FIG. 10 is similar to the characteristic impedance control structure 200 shown in FIG. 5. The same or similar descriptions will be adaptively omitted below.

In this embodiment, the characteristic impedance control structure 300 includes a substrate 30, a plurality of first transmission lines 31, 31′, a first ground pattern 32, a plurality of second transmission lines 33, 33′, a plurality of ground lines 34, 34′, a first dielectric layer 351, a second dielectric layer 352, a first ground layer 361, a second ground layer 362, a third transmission line 37, a second ground pattern 38 and a plurality of conductive vias 391, 391′. The substrate 30 may be a printed circuit board, a glass substrate, a silicon substrate or other substrates commonly used in circuits. The substrate 30 has an upper surface 30a and a lower surface 30b opposite to each other. The upper surface 30a is a first plane. The lower surface 30b is a second plane. The first transmission lines 31, 31′ and the first ground pattern 32 are disposed on the upper surface 30a of the substrate 30. The first transmission lines 31, 31′ and the first ground pattern 32 extend along the upper surface 30a. The upper surface 30a is substantially parallel to a XY plane in the figure.

The second transmission lines 33, 33′ extend along a direction PD and are respectively electrically connected to the first transmission lines 31, 31′. The second transmission lines 33, 33′ penetrate through the substrate 30. The direction PD is substantially parallel to a Z direction in the figure. In this embodiment, the direction PD is substantially perpendicular to the upper surface 30a of the substrate 30, but the disclosure is not limited thereto.

In this embodiment, the ground lines 34, 34′ form a ground component. The ground lines 34, 34′ extend along the direction PD and are electrically connected to the first ground pattern 32. The ground lines 34, 34′ penetrate through the substrate 30. Each of the ground lines 34, 34′ is next to and spaced from the second transmission lines 33, 33′.

The first dielectric layer 351 is disposed on the first transmission lines 31, 31′, the first ground pattern 32 and the upper surface 30a of the substrate 30. The first ground layer 361 is disposed on the first dielectric layer 351. The first ground layer 361 is disposed substantially parallel to the upper surface 30a. In the direction PD, the first ground layer 361 is farther away from the second transmission lines 33, 33′ than the first ground pattern 32. The conductive vias 391, 391′ are respectively electrically connected to the first transmission lines 31, 31′. The conductive vias 391, 391′ penetrate through the first dielectric layer 351 and the first ground layer 361. The first transmission lines 31, 31′ may be respectively electrically connected to the outside through the conductive vias 391, 391′.

The third transmission line 37 and the second ground pattern 38 are disposed on the lower surface 30b of the substrate 30. The third transmission line 37 and the second ground pattern 38 extend along the lower surface 30b. The lower surface 30b is substantially parallel to a XY plane in the figure. The ground lines 34, 34′ are electrically connected to the second ground pattern 38. The top ends of the second transmission lines 33, 33′ are respectively electrically connected to the first transmission lines 31, 31′. The two ends of the third transmission line 37 are respectively electrically connected to the bottom ends of the second transmission lines 33, 33′. Thereby, the two ends of the second transmission line 33 are respectively electrically connected to the first transmission line 31 and the third transmission line 37. The two ends of the second transmission line 33′ are respectively electrically connected to the first transmission line 31′ and the third transmission line 37. In this embodiment, the direction PD is substantially perpendicular to the lower surface 30b of the substrate 30, but the disclosure is not limited thereto.

In this embodiment, the second dielectric layer 352 is disposed on the third transmission line 37, the second ground pattern 38 and the lower surface 30b of the substrate 30. The second ground layer 362 is disposed on the second dielectric layer 352. The second ground layer 362 is disposed substantially parallel to the lower surface 30b. In the direction PD, the second ground layer 362 is farther away from the second transmission lines 33, 33′ than the second ground pattern 38.

In this embodiment, the transmission path includes the first transmission line 31, the second transmission line 33, the third transmission line 37, the second transmission line 33′ and the first transmission line 31′. In other embodiments, the first transmission line 31′, the second transmission line 33′ and the ground line 34′ may be omitted as required.

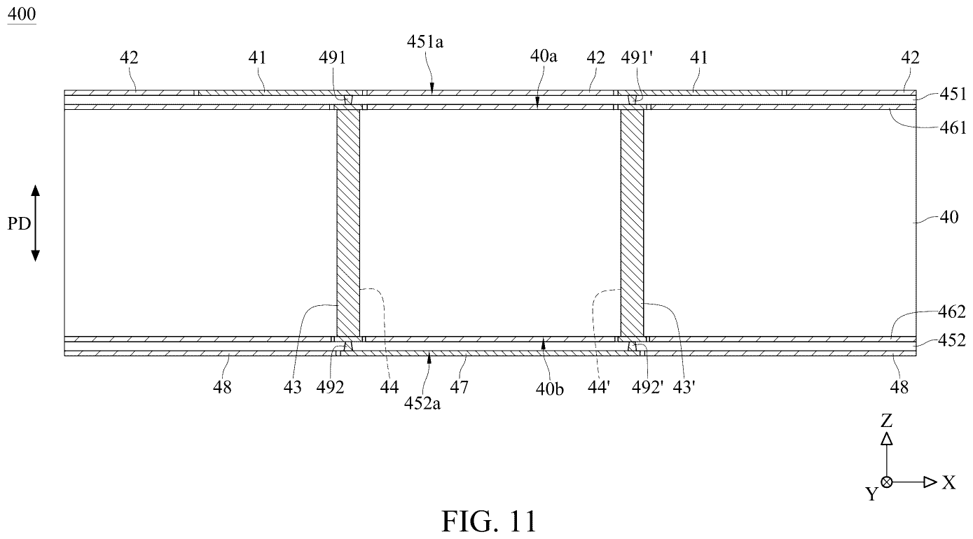

Please refer to FIG. 11. FIG. 11 illustrates a schematic side cross-sectional view of a characteristic impedance control structure according to another embodiment of the disclosure. The characteristic impedance control structure 400 shown in FIG. 11 is similar to the characteristic impedance control structure 200 shown in FIG. 5. The same or similar descriptions will be adaptively omitted below.

In this embodiment, the characteristic impedance control structure 400 includes a substrate 40, a plurality of first transmission lines 41, 41′, a first ground pattern 42, a plurality of second transmission lines 43, 43′, a plurality of ground lines 44, 44′, a first dielectric layer 451, a second dielectric layer 452, a first ground layer 461, a second ground layer 462, a third transmission line 47, a second ground pattern 48 and a plurality of conductive vias 491, 491′, 492, 492′. The substrate 40 may be a printed circuit board, a glass substrate, a silicon substrate or other substrates commonly used in circuits. The substrate 40 has an upper surface 40a and a lower surface 40b opposite to each other. The upper surface 40a and the lower surface 40b are substantially parallel to a XY plane in the figure.

The second transmission lines 43, 43′ extend along a direction PD. The second transmission lines 43, 43′ penetrate through the substrate 40. The direction PD is substantially parallel to a Z direction in the figure. The ground lines 44, 44′ form a ground component. The ground lines 44, 44′ extend along the direction PD. The ground lines 44, 44′ penetrate through the substrate 40. Each of the ground lines 44, 44′ is next to and spaced from the second transmission lines 43, 43′.

The first ground layer 461 is disposed on the upper surface 40a of the substrate 40. The second transmission lines 43, 43′ are spaced from the first ground layer 461. The ground lines 44, 44′ are electrically connected to the first ground layer 461. The first ground layer 461 is disposed substantially parallel to the upper surface 40a. The first dielectric layer 451 is disposed on the first ground layer 461. The first transmission lines 41, 41′ and the first ground pattern 42 are disposed on the first dielectric layer 451. The conductive vias 491, 491′ penetrate through the first dielectric layer 451. The first transmission line 41 is electrically connected to the top end of the second transmission line 43 through the conductive via 491. The first transmission line 41′ is electrically connected to the top end of the second transmission line 43′ through the conductive via 491′. The first transmission lines 41, 41′ may be directly electrically connected to the outside. In the direction PD, the first ground pattern 42 is farther away from the second transmission lines 43, 43′ than the first ground layer 461. The first transmission lines 41, 41′ and the first ground pattern 42 extend along an upper surface 451a of the first dielectric layer 451. The upper surface 451a of the first dielectric layer 451 is a first plane. In this embodiment, the direction PD is substantially perpendicular to the upper surface 451a of the first dielectric layer 451, but the disclosure is not limited thereto.

In this embodiment, the second ground layer 462 is disposed on the lower surface 40b of the substrate 40. The second transmission lines 43, 43′ are spaced from the second ground layer 462. The ground lines 44, 44′ are electrically connected to the second ground layer 462. The second ground layer 462 is disposed substantially parallel to the lower surface 40b. The second dielectric layer 452 is disposed on the second ground layer 462. The third transmission line 47 and the second ground pattern 48 are disposed on the second dielectric layer 452. The conductive vias 492, 492′ penetrate through the second dielectric layer 452. The two ends of the third transmission line 47 are respectively electrically connected to the bottom ends of the second transmission lines 43, 43′ through the conductive vias 492, 492′. Thereby, the two ends of the second transmission line 43 are respectively electrically connected to the first transmission line 41 and the third transmission line 47. The two ends of the second transmission line 43′ are respectively electrically connected to the first transmission line 41′ and the third transmission line 47. In the direction PD, the second ground pattern 48 is farther away from the second transmission lines 43, 43′ than the second ground layer 462. The third transmission line 47 and the second ground pattern 48 extend along a lower surface 452a of the second dielectric layer 452. The ground lines 44, 44′ may be indirectly electrically connected to the first ground pattern 42 and the second ground pattern 48. The lower surface 452a of the second dielectric layer 452 is a second plane. In this embodiment, the direction PD is substantially perpendicular to the lower surface 452a of the second dielectric layer 452, but the disclosure is not limited thereto.

In this embodiment, the transmission path includes the first transmission line 41, the conductive via 491, the second transmission line 43, the conductive via 492, the third transmission line 47, the conductive via 492′, the second transmission line 43′, the conductive via 491′ and the first transmission line 41′. In other embodiments, the conductive via 492′, the second transmission line 43′, the conductive via 491′, the first transmission line 41′ and the ground line 44′ may be omitted as required.

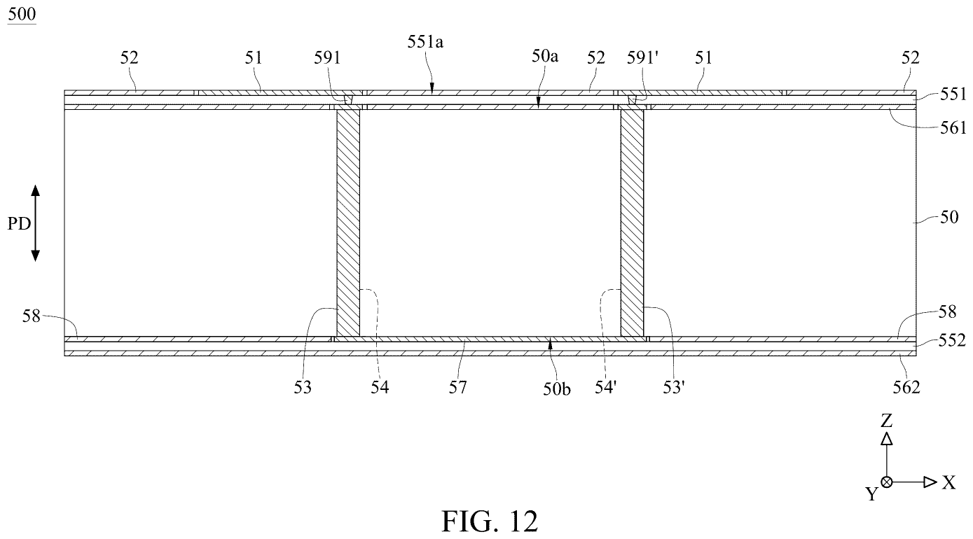

Please refer to FIG. 12. FIG. 12 illustrates a schematic side cross-sectional view of a characteristic impedance control structure according to another embodiment of the disclosure. The characteristic impedance control structure 500 shown in FIG. 12 is similar to the characteristic impedance control structure 200 shown in FIG. 5. The same or similar descriptions will be adaptively omitted below.

In this embodiment, the characteristic impedance control structure 500 includes a substrate 50, a plurality of first transmission lines 51, 51′, a first ground pattern 52, a plurality of second transmission lines 53, 53′, a plurality of ground lines 54, 54′, a first dielectric layer 551, a second dielectric layer 552, a first ground layer 561, a second ground layer 562, a third transmission line 57, a second ground pattern 58 and a plurality of conductive vias 591, 591′. The substrate 50 may be a printed circuit board, a glass substrate, a silicon substrate or other substrates commonly used in circuits. The substrate 50 has an upper surface 50a and a lower surface 50b opposite to each other. The upper surface 50a and the lower surface 50b are substantially parallel to a XY plane in the figure.

The second transmission lines 53, 53′ extend along a direction PD. The second transmission lines 53, 53′ penetrate through the substrate 50. The direction PD is substantially parallel to a Z direction in the figure. The ground lines 54, 54′ form a ground component. The ground lines 54, 54′ extend along the direction PD. The ground lines 54, 54′ penetrate through the substrate 50. Each of the ground lines 54, 54′ is next to and spaced from the second transmission lines 53, 53′.

The first ground layer 561 is disposed on the upper surface 50a of the substrate 50. The second transmission lines 53, 53′ are spaced from the first ground layer 561. The ground lines 54, 54′ are electrically connected to the first ground layer 561. The first ground layer 561 is disposed substantially parallel to the upper surface 50a. The first dielectric layer 551 is disposed on the first ground layer 561. The first transmission lines 51, 51′ and the first ground pattern 52 are disposed on the first dielectric layer 551. The conductive vias 591, 591′ penetrate through the first dielectric layer 551. The first transmission line 51 is electrically connected to the top end of the second transmission line 53 through the conductive via 591. The first transmission line 51′ is electrically connected to the top end of the second transmission line 53′ through the conductive via 591′. The first transmission lines 51, 51′ may be directly electrically connected to the outside. In the direction PD, the first ground pattern 52 is farther away from the second transmission lines 53, 53′ than the first ground layer 561. The ground lines 54, 54′ may be indirectly electrically connected to the first ground pattern 52. The first transmission lines 51, 51′ and the first ground pattern 52 extend along an upper surface 551a of the first dielectric layer 551. The upper surface 551a of the first dielectric layer 551 is a first plane. In this embodiment, the direction PD is substantially perpendicular to the upper surface 551a of the first dielectric layer 551, but the disclosure is not limited thereto.

In this embodiment, the third transmission line 57 and the second ground pattern 58 are disposed on the lower surface 50b of the substrate 50. The lower surface 50b is a second plane. The third transmission line 57 and the second ground pattern 58 extend along the lower surface 50b. The lower surface 50b is substantially parallel to a XY plane in the figure. The ground lines 54, 54′ are electrically connected to the second ground pattern 58. The two ends of the third transmission line 57 are respectively electrically connected to the bottom ends of the second transmission lines 53, 53′. Thereby, the two ends of the second transmission line 53 are respectively electrically connected to the first transmission line 51 and the third transmission line 57. The two ends of the second transmission line 53′ are respectively electrically connected to the first transmission line 51′ and the third transmission line 57. In this embodiment, the direction PD is substantially perpendicular to the lower surface 50b of the substrate 50, but the disclosure is not limited thereto.

In this embodiment, the second dielectric layer 552 is disposed on the third transmission line 57, the second ground pattern 58 and the lower surface 50b of the substrate 50. The second ground layer 562 is disposed on the second dielectric layer 552. The second ground layer 562 is disposed substantially parallel to the lower surface 50b. In the direction PD, the second ground layer 562 is farther away from the second transmission lines 53, 53′ than the second ground pattern 58.

In this embodiment, the transmission path includes the first transmission line 51, the conductive via 591, the second transmission line 53, the third transmission line 57, the second transmission line 53′, the conductive via 591′ and the first transmission line 51′. In other embodiments, the second transmission line 53′, the conductive via 591′, the first transmission line 51′ and the ground line 54′ may be omitted as required.

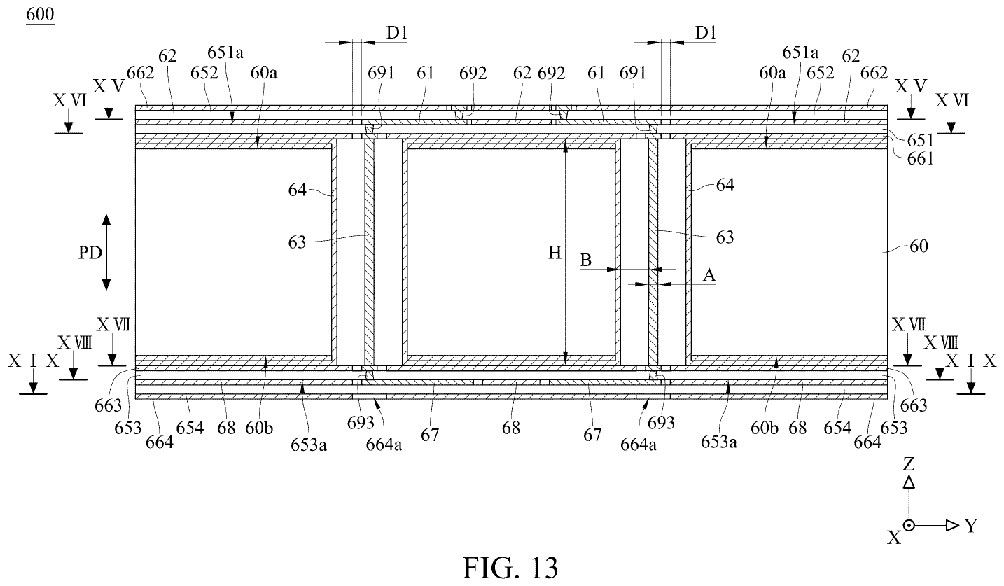

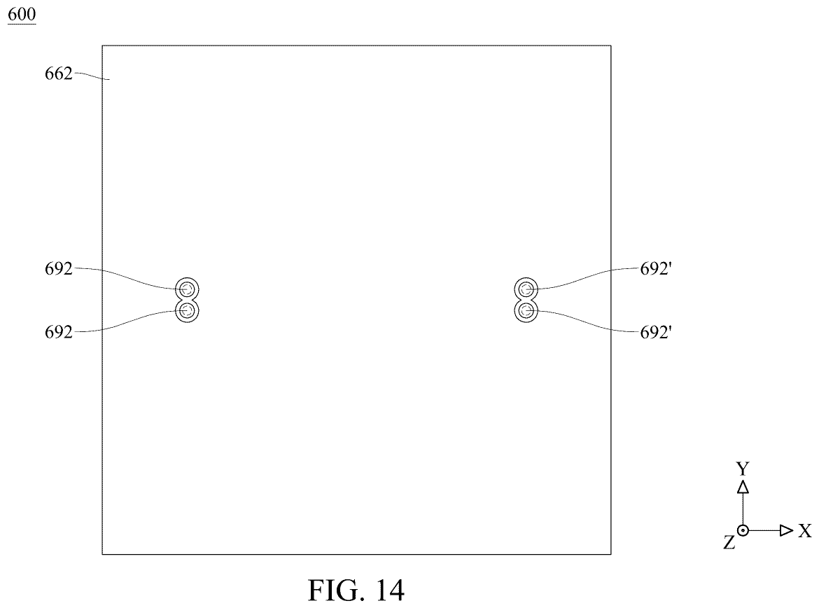

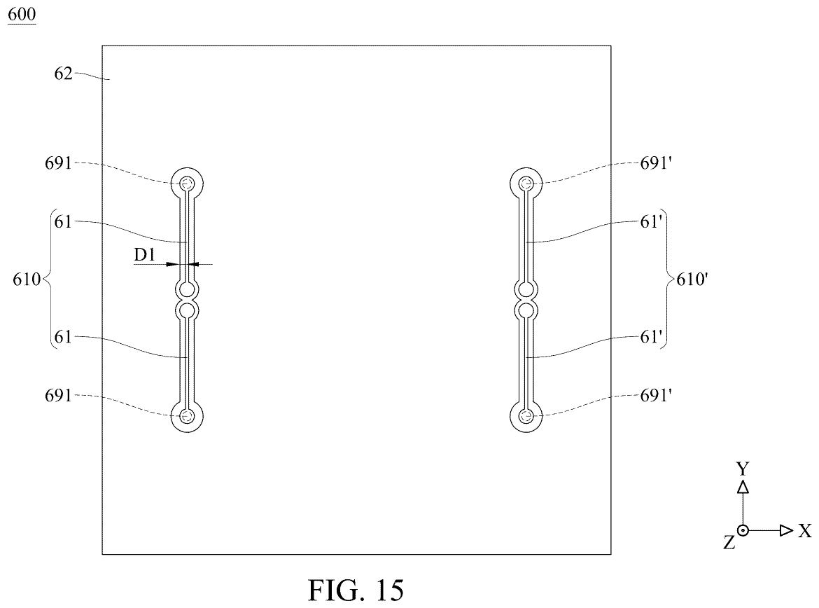

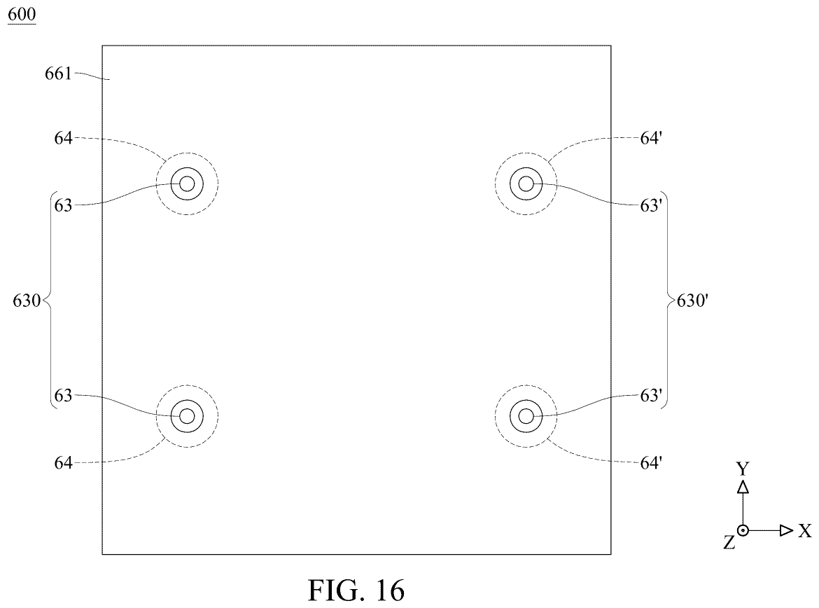

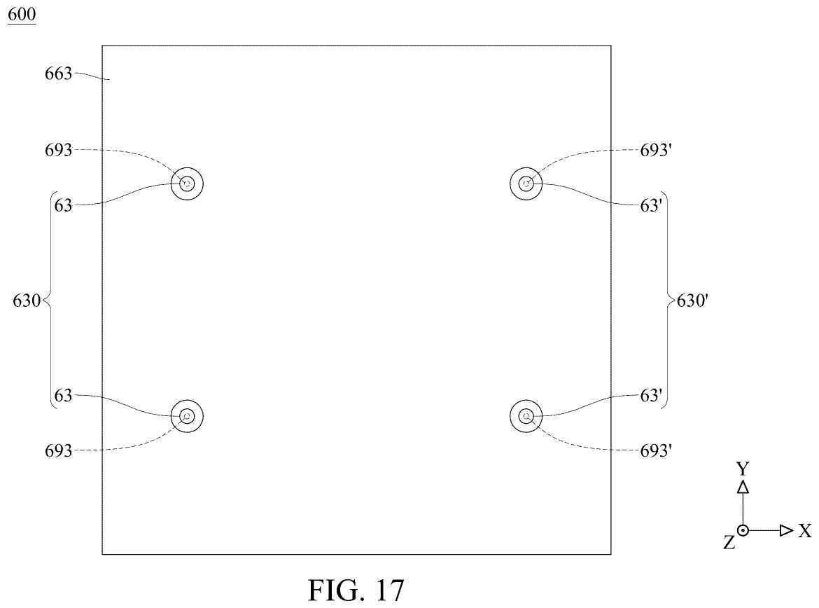

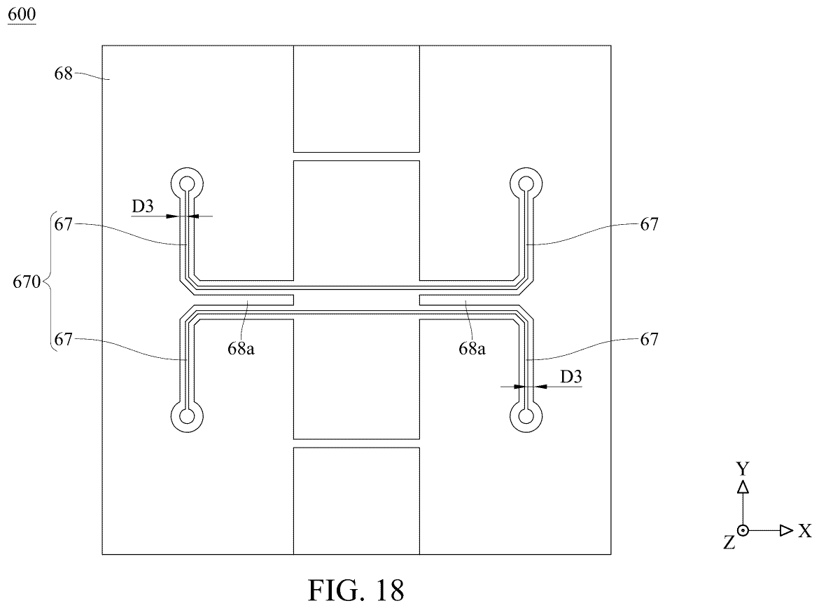

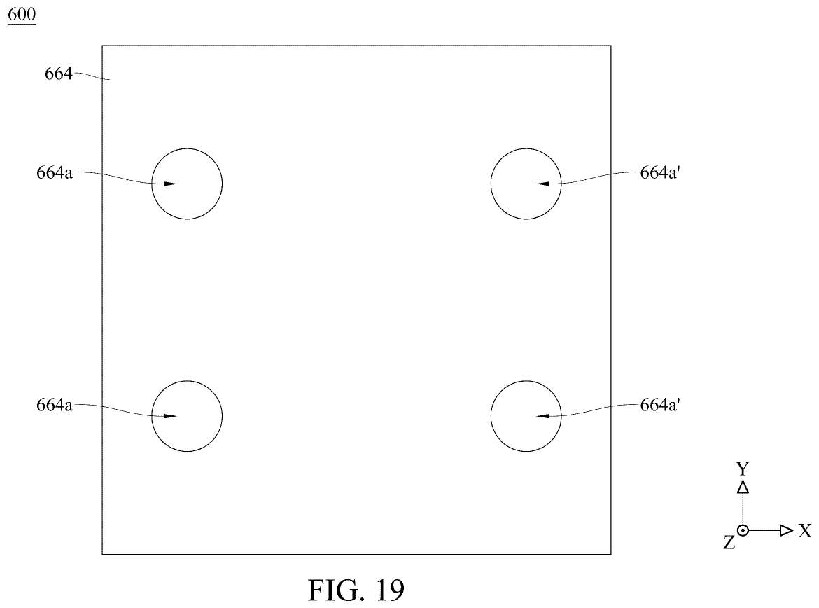

Please refer to FIG. 13 to FIG. 19. FIG. 13 illustrates a schematic side cross-sectional view of a characteristic impedance control structure according to another embodiment of the disclosure. FIG. 14 illustrates a schematic top cross-sectional view of the characteristic impedance control structure in FIG. 13. FIG. 15 illustrates a schematic top cross-sectional view along line XV-XV of the characteristic impedance control structure in FIG. 13. FIG. 16 illustrates a schematic top cross-sectional view along line XVI-XVI of the characteristic impedance control structure in FIG. 13. FIG. 17 illustrates a schematic top cross-sectional view along line XVII-XVII of the characteristic impedance control structure in FIG. 13. FIG. 18 illustrates a schematic top cross-sectional view along line XVIII-XVIII of the characteristic impedance control structure in FIG. 13. FIG. 19 illustrates a schematic top cross-sectional view along line XIX-XIX of the characteristic impedance control structure in FIG. 13. The characteristic impedance control structure 600 shown in FIG. 13 is similar to the characteristic impedance control structure 200 shown in FIG. 5. The same or similar descriptions will be adaptively omitted below.

As shown in FIG. 13 and FIG. 19, in this embodiment, the characteristic impedance control structure 600 includes a substrate 60, a plurality of first differential transmission lines 61, 61′, a first ground pattern 62, a plurality of second differential transmission lines 63, 63′, a plurality of ground tubes 64, 64′, a first dielectric layer 651, a second dielectric layer 652, a third dielectric layer 653, a fourth dielectric layer 654, a first ground layer 661, a second ground layer 662, a third ground layer 663, a fourth ground layer 664, a plurality of third differential transmission lines 67, a second ground pattern 68 and a plurality of conductive vias 691, 691′, 692, 692′, 693, 693′. The substrate 60 may be a printed circuit board, a glass substrate, a silicon substrate or other substrates commonly used in circuits. The substrate 60 has an upper surface 60a and a lower surface 60b opposite to each other. The upper surface 60a and the lower surface 60b are substantially parallel to a XY plane in the figure. The first differential transmission lines 61 form a first transmission line 610. The first differential transmission lines 61′ form a first transmission line 610′. The second differential transmission lines 63 form a second transmission line 630. The second differential transmission lines 63′ form a second transmission line 630′. The third differential transmission lines 67 form a third transmission line 670.

As shown in FIG. 13 and FIG. 16, the second differential transmission lines 63, 63′ extend along a direction PD. The second differential transmission lines 63, 63′ penetrate through the substrate 60. Each of the second differential transmission lines 63, 63′ has an outer diameter A. The direction PD is substantially parallel to a Z direction in the figure. The ground tubes 64, 64′ form a ground component. The ground tubes 64, 64′ extend along the direction PD. The ground tubes 64, 64′ penetrate through the substrate 60. Each of the ground tubes 64, 64′ is disposed around and spaced from each of the second differential transmission lines 63, 63′ by a second distance B. Each of the ground tubes 64, 64′ has a length H along the direction PD. The first ground layer 661 is disposed on the upper surface 60a of the substrate 60. The second differential transmission lines 63, 63′ are spaced from the first ground layer 661. The ground tubes 64, 64′ are electrically connected to the first ground layer 661. The first ground layer 661 is disposed substantially parallel to the upper surface 60a.

As shown in FIG. 13 and FIG. 15, the first dielectric layer 651 is disposed on the first ground layer 661. The first differential transmission lines 61, 61′ and the first ground pattern 62 are disposed on the first dielectric layer 651. The first ground pattern 62 is spaced from each of the first differential transmission lines 61, 61′ by a first distance D1. The first distance D1 is less than or equal to twice the length H (that is D1≤2H) (when the first distance D1 is inconsistent, the maximum value is taken). The second distance B is less than or equal to five times the outer diameter A (that is B≤5A).

The conductive vias 691, 691′ penetrate through the first dielectric layer 651. The first differential transmission lines 61 are electrically connected to the top ends of the second differential transmission lines 63 through the conductive vias 691. The first differential transmission lines 61′ are electrically connected to the top ends of the second differential transmission lines 63′ through the conductive vias 691′. In the direction PD, the first ground pattern 62 is farther away from the second differential transmission lines 63, 63′ than the first ground layer 661. The first differential transmission lines 61, 61′ and the first ground pattern 62 extend along an upper surface 651a of the first dielectric layer 651. The upper surface 651a of the first dielectric layer 651 is a first plane. In this embodiment, the direction PD is substantially perpendicular to the upper surface 651a of the first dielectric layer 651, but the disclosure is not limited thereto.

As shown in FIG. 13 and FIG. 14, the second dielectric layer 652 is disposed on the first differential transmission lines 61, 61′, the first ground pattern 62 and the upper surface 651a of the first dielectric layer 651. The second ground layer 662 is disposed on the second dielectric layer 652. The second ground layer 662 is disposed substantially parallel to the upper surface 651a. In the direction PD, the second ground layer 662 is farther away from the second differential transmission lines 63, 63′ than the first ground pattern 62. The conductive vias 692, 692′ are respectively electrically connected to the first differential transmission lines 61, 61′. The conductive vias 692, 692′ penetrate through the second dielectric layer 652 and the second ground layer 662. The first differential transmission lines 61, 61′ may be respectively electrically connected to the outside through the conductive vias 692, 692′.

As shown in FIG. 13, FIG. 16 and FIG. 17, the third ground layer 663 is disposed on the lower surface 60b of the substrate 60. The second differential transmission lines 63, 63′ are spaced from the third ground layer 663. The ground tubes 64, 64′ are electrically connected to the third ground layer 663. The third ground layer 663 is disposed substantially parallel to the lower surface 60b.

As shown in FIG. 13, FIG. 17 and FIG. 18, the third dielectric layer 653 is disposed on the third ground layer 663. The third differential transmission lines 67 and the second ground pattern 68 are disposed on the third dielectric layer 653. The second ground pattern 68 is spaced from each of the third differential transmission lines 67 by a third distance D3. The third distance D3 is less than or equal to twice the length H (that is D3≤2H). A portion 68a of the second ground pattern 68 extends to where between the third differential transmission lines 67. The conductive vias 693, 693′ penetrate through the third dielectric layer 653. The two ends of each of the third differential transmission lines 67 are respectively electrically connected to the bottom ends of the second differential transmission lines 63, 63′ through the conductive vias 693, 693′. In the direction PD, the second ground pattern 68 is farther away from the second differential transmission lines 63, 63′ than the third ground layer 663. The third differential transmission lines 67 and the second ground pattern 68 extend along a lower surface 653a of the third dielectric layer 653. The lower surface 653a of the third dielectric layer 653 is a second plane. In this embodiment, the direction PD is substantially perpendicular to the lower surface 653a of the third dielectric layer 653, but the disclosure is not limited thereto.

As shown in FIG. 13 and FIG. 19, the fourth dielectric layer 654 is disposed on the third differential transmission lines 67, the second ground pattern 68 and the lower surface 653a of the third dielectric layer 653. The fourth ground layer 664 is disposed on the fourth dielectric layer 654. The fourth ground layer 664 is disposed substantially parallel to the lower surface 653a. In the direction PD, the fourth ground layer 664 is farther away from the second differential transmission lines 63, 63′ than the second ground pattern 68. The fourth ground layer 664 has a plurality of openings 664a, 664a′. A plurality of projections of the second differential transmission lines 63, 63′ to the fourth ground layer 664 are respectively disposed overlapping with the openings 664a, 664a′. The greater the openings 664a, 664a′ are, the greater the characteristic impedances of the second differential transmission lines 63, 63′ are. The smaller the openings 664a, 664a′ are, the less the characteristic impedances of the second differential transmission lines 63, 63′ arc.

In this embodiment, the transmission path includes the conductive vias 692, the first transmission line 610, the conductive vias 691, the second transmission line 630, the conductive vias 693, the third transmission line 670, the conductive vias 693′, the second transmission line 630′, the conductive vias 691′, the first transmission line 610′ and the conductive vias 692′. In other embodiments, the conductive vias 693′, the second transmission line 630′, the conductive vias 691′, the first transmission line 610′, the conductive vias 692′ and the ground tube 64′ may be omitted as required.

As discussed above, in the characteristic impedance control structure in one embodiment of the disclosure, by means of the corresponding relationship of the distance between the first transmission line and the ground pattern, the size of the second transmission line, the size of the ground component and the distance between the second transmission line and the ground component, the characteristic impedances of the first transmission line and the second transmission line may be matched with each other. When the first transmission line and the second transmission line are used to transmit a high frequency signal, it may prevent the signal passing through the transmission path from being distorted due to characteristic impedance mismatch.

Although the disclosure is disclosed in the foregoing embodiments, it is not intended to limit the disclosure. All variations and modifications made without departing from the spirit and scope of the disclosure fall within the scope of the disclosure. For the scope defined by the disclosure, please refer to the attached claims.

What is claimed is:

1. A characteristic impedance control structure, comprising:
a first transmission line, extending along a first plane;
a first ground pattern, extending along the first plane, wherein the first ground pattern is spaced from the first transmission line by a first distance;
a second transmission line, extending along a direction and electrically connected to the first transmission line, wherein a first angle between the direction and the first plane is greater than zero, and the second transmission line has an outer diameter; and
a ground component, extending along the direction and electrically connected to the first ground pattern, wherein the ground component is next to and spaced from the second transmission line by a second distance, the ground component has a length along the direction, the first distance is less than or equal to twice the length, the second distance is less than or equal to five times the outer diameter.

2. The characteristic impedance control structure according to claim 1, further comprising a ground layer, wherein the ground layer is disposed substantially parallel to the first plane, and the ground layer is farther away from the second transmission line than the first ground pattern in the direction.

3. The characteristic impedance control structure according to claim 1, further comprising a ground layer and a conductive via, wherein the ground layer is disposed substantially parallel to the first plane, the second transmission line is spaced from the ground layer, the first ground pattern is farther away from the second transmission line than the ground layer in the direction, and the first transmission line is electrically connected to the second transmission line through the conductive via.

4. The characteristic impedance control structure according to claim 1, further comprising a third transmission line and a second ground pattern, wherein the third transmission line and the second ground pattern extend along a second plane, a second angle between the direction and the second plane is greater than zero, two ends of the second transmission line are respectively electrically connected to the first transmission line and the third transmission line, the second ground pattern is spaced from the third transmission line by a third distance, and the third distance is less than or equal to twice the length.

5. The characteristic impedance control structure according to claim 4, further comprising a ground layer, wherein the ground layer is disposed substantially parallel to the second plane, and the ground layer is farther away from the second transmission line than the second ground pattern in the direction.

6. The characteristic impedance control structure according to claim 4, further comprising a ground layer and a conductive via, wherein the ground layer is disposed substantially parallel to the second plane, the second transmission line is spaced from the ground layer, the second ground pattern is farther away from the second transmission line than the ground layer in the direction, and the third transmission line is electrically connected to the second transmission line through the conductive via.

7. The characteristic impedance control structure according to claim 1, wherein the ground component comprises a plurality of ground lines, and the plurality of ground lines are arranged around the second transmission line.

8. The characteristic impedance control structure according to claim 1, wherein the ground component comprises a ground tube, and the ground tube is disposed around the second transmission line.

9. The characteristic impedance control structure according to claim 1, wherein the first transmission line comprises a pair of first differential transmission lines, the second transmission line comprises a pair of second differential transmission lines, the first ground pattern is spaced from the pair of first differential transmission lines by the first distance, each of the pair of second differential transmission lines has the outer diameter, and the ground component is spaced from the pair of second differential transmission lines by the second distance.

10. The characteristic impedance control structure according to claim 9, further comprising a ground layer, wherein the ground layer is disposed substantially parallel to the first plane, and the ground layer is farther away from the second transmission line than the first ground pattern in the direction.

11. The characteristic impedance control structure according to claim 9, further comprising a ground layer and a conductive via, wherein the ground layer is disposed substantially parallel to the first plane, the second transmission line is spaced from the ground layer, the first ground pattern is farther away from the second transmission line than the ground layer in the direction, and the first transmission line is electrically connected to the second transmission line through the conductive via.

12. The characteristic impedance control structure according to claim 9, further comprising a third transmission line and a second ground pattern, wherein the third transmission line and the second ground pattern extend along a second plane, a second angle between the direction and the second plane is greater than zero, the third transmission line comprises a pair of third differential transmission lines, two ends of each of the pair of second differential transmission lines are respectively electrically connected to each of the pair of first differential transmission lines and each of the pair of third differential transmission lines, the second ground pattern is spaced from each of the pair of third differential transmission lines by a third distance, and the third distance is less than or equal to twice the length.

13. The characteristic impedance control structure according to claim 12, wherein a portion of the second ground pattern extends to where between the pair of third differential transmission lines.

14. The characteristic impedance control structure according to claim 12, further comprising a ground layer, wherein the ground layer is disposed substantially parallel to the second plane, and the ground layer is farther away from the second transmission line than the second ground pattern in the direction.

15. The characteristic impedance control structure according to claim 14, wherein the ground layer has a plurality of openings, and a plurality of projections of the pair of second differential transmission lines to the ground layer are respectively disposed overlapping with the plurality of openings.

16. The characteristic impedance control structure according to claim 12, further comprising a ground layer and a conductive via, wherein the ground layer is disposed substantially parallel to the second plane, the second transmission line is spaced from the ground layer, the second ground pattern is farther away from the second transmission line than the ground layer in the direction, and the third transmission line is electrically connected to the second transmission line through the conductive via.
